(19) United States
(12) Patent Application Publication
(10) Pub. No.: US 2017/0338387 A1
(43) Pub. Date: Nov. 23, 2017

(54) LIGHT EMITTING DIODE

(71) Applicant: Seoul Semiconductor Co., Ltd., Ansan-si (KR)

(72) Inventors: Hyuck Jun Kim, Ansan-si (KR); Jae Wan Song, Ansan-si (KR); Jae Hyun Park, Ansan-si (KR); So Mi Park, Ansan-si (KR); Ki Bum Nam, Ansan-si (KR)

(21) Appl. No.: 15/673,372

(22) Filed: Aug. 9, 2017

Related U.S. Application Data
(63) Continuation-in-part of application No. 15/198,957, filed on Jun. 30, 2016.

(30) Foreign Application Priority Data
Jun. 30, 2015 (KR) 10-2015-0093540

(51) Int. Cl. H01L 33/50; H01L 33/56; C09K 11/77; C09K 11/64; C09K 11/61; H01L 33/58; H01L 33/54; C09K 11/08

(52) U.S. Cl. CPC H01L 33/504; H01L 33/58; H01L 33/56; H01L 33/54; C09K 11/7734; C09K 11/7706; C09K 11/646; C09K 11/61; C09K 11/0883

(57) ABSTRACT

A light emitting apparatus, including: a substrate; a light emitting diode disposed on the substrate; and a lens covering the light emitting diode. The light emitting diode includes a light emitting diode chip; a first molding portion covering the light emitting diode chip; a second molding portion covering the first molding portion. The first molding portion includes one or more kinds of phosphors and the second molding portion contains no phosphors. The light emitting diode chip is covered by a first molding portion having a high index of refraction and a second molding portion having a low index of refraction and covering the first molding portion in order to reduce total reflection in the molding portions through reduction in difference in index of refraction between external air and the molding portion having a high index of refraction, thereby increasing the quantity of light.

### CROSS-REFERENCE TO RELATED APPLICATIONS

This application is a Continuation-in-Part of U.S. patent application Ser. No. 15/198,957, filed on Jun. 30, 2016, and claims priority from and the benefit of Korean Patent Application No. 10-2015-0093540, filed on Jun. 30, 2015, each of which is hereby incorporated by reference for all purposes as if fully set forth herein.

### BACKGROUND

### Field

Exemplary embodiments of the present disclosure relate to a light emitting diode, and more particularly, to a light emitting diode including a molding portion molding a light emitting diode chip.

### Discussion of the Background

A light emitting diode (LED) is an eco-friendly product with various advantages such as high luminous efficacy, long lifespan, and low power consumption. In addition, the light emitting diode can be fabricated in a package structure having a light emitting diode chip therein depending upon purposes or shapes thereof and thus has a wide application range.

In a light emitting diode package a light emitting diode chip may be mounted on a substrate and covered by a molding portion which serves to protect the light emitting diode chip. If the light emitting diode chip is a blue or UV light emitting diode chip, the light emitting diode package may employ phosphors to emit white light. The phosphors may be separately provided to the light emitting diode package or may be contained in the molding portion.

Since the molding portion serves to protect the light emitting diode chip, the molding portion may be formed to cover the light emitting diode chip. Thus, the molding portion is formed of a material having high light transmittance in order to allow light emitted from the light emitting diode chip to efficiently pass therethrough. Typically, the molding portion is formed of a silicone resin, for example, a high refractive index (HRI) silicone resin having an index of refraction of about 1.53.

In the structure wherein the phosphors are dispersed in the molding portion upon formation of the molding portion using such HRI silicone, the index of refraction of the molding portion can be further increased by the phosphors. Since the phosphors have an index of refraction of about 1.8 to 2.0, the molding portion having the phosphors dispersed therein has an index of refraction of about 1.7 or higher.

As such, in the structure wherein the light emitting diode chip is molded in the molding portion containing the phosphors, a large quantity of light emitted from the light emitting diode chip is blocked by the molding portion. This is caused by a difference in index of refraction between the molding portion and external air. That is, a higher index of refraction of the molding portion provides a greater difference in index of refraction between the molding portion and external air, thereby causing frequent occurrence of total reflection at an interface between the molding portion and the external air.

As such, the light emitting diode employing the molding portion with the phosphors dispersed therein has a problem of reduction in quantity of light.

### SUMMARY

Exemplary embodiments of the present disclosure provide a light emitting diode configured to mold a light emitting diode chip using a molding portion with phosphors dispersed therein while securing a high quantity of light.

In accordance with one aspect of the present disclosure, A light emitting apparatus, comprising: a substrate; a light emitting diode disposed on the substrate; a lens covering the light emitting diode; wherein the light emitting diode comprising a light emitting diode chip; a first molding portion covering the light emitting diode chip; a second molding portion covering the first molding portion, wherein: the first molding portion comprises one or more kinds of phosphors and the second molding portion is free of phosphor.

Wherein the phosphors comprise at least one selected from green phosphor, cyan phosphors, yellow phosphors and red phosphors. Wherein the phosphors comprise at least one selected from garnet phosphor, aluminate phosphor, sulfide phosphor, oxynitride phosphor, nitride phosphor, fluoride phosphor and silicate phosphor.

Wherein the fluoride phosphor have a composition of A₂MF₆: Mn⁴⁺, a can be selected from K, Na and Rb, and M can be selected from Si, Ge, Sn, Pb, Al, Ga, In and Ti. Wherein the A₂MF₆: Mn⁴⁺ phosphor emits red wavelength and shows narrow emission peak wavelength under 10 μm. Wherein the surface of the A₂MF₆: Mn⁴⁺ phosphor is covered by the material A₂MF₆ without Mn or fluoride.

Wherein the oxynitride phosphor comprises β-SiAlON:Eu²⁺.

A light emitting diode, comprising: a light emitting diode chip; a first molding portion covering the light emitting diode chip; a second molding portion covering the first molding portion, wherein: the first molding portion comprises one or more kinds of phosphors and the second molding portion is free of phosphor, the first molding portion has rectangular shape and the second molding portion has rectangular shape.

The total thickness of the first molding portion and second molding portion is thinner than the half of the chip width in horizontal direction. The second molding portion has thinner thickness than the first molding portion.

Wherein the phosphors comprise at least one selected from green phosphor, cyan phosphors, yellow phosphors and red phosphors. Wherein the phosphors comprise at least one selected from garnet phosphor, aluminate phosphor, sulfide phosphor, oxynitride phosphor, nitride phosphor, fluoride phosphor and silicate phosphor. Wherein the fluoride phosphor have a composition of A₂MF₆: Mn⁴⁺, a can be selected from K, Na and Rb, and M can be selected from Si, Ge, Sn, Pb, Al, Ga, In and Ti.

Wherein the A₂MF₆: Mn⁴⁺ phosphor emits red wavelength and shows narrow emission peak wavelength under 10 μm. Wherein the surface of the A₂MF₆: Mn⁴⁺ phosphor is covered by the material A₂MF₆ without Mn or fluoride.

Wherein the oxynitride phosphor comprises β-SiAlON:Eu²⁺.

According to exemplary embodiments, the light emitting diode includes a molding portion covering a light emitting diode chip and having a high index of refraction and another molding portion covering the molding portion and having a low index of refraction in order to reduce total reflection in the molding portions through reduction in difference in index of refraction between external air and the molding portion having a high index of refraction, thereby increasing the quantity of light emitted from the light emitting diode.

### BRIEF DESCRIPTION OF THE DRAWINGS

FIG. 1 is a sectional view of a light emitting diode according to one exemplary embodiment of the present disclosure.

FIG. 2 is a view illustrating the light emitting diode according to the exemplary embodiment of the present disclosure.

FIG. 3(a) and FIG. 3(b) are views illustrating variation in light transmittance depending upon the number of molding portions.

FIG. 4 is a sectional view of a light emitting diode according to another exemplary embodiment of the present disclosure.

FIG. 5 shows a table of test results as to quantity of light depending upon thickness of a second molding portion.

FIG. 6 is a sectional view of a light emitting diode according to a further exemplary embodiment of the present disclosure.

### DETAILED DESCRIPTION OF THE ILLUSTRATED EMBODIMENTS

Hereinafter, exemplary embodiments of the present disclosure will be described in detail with reference to the accompanying drawings.

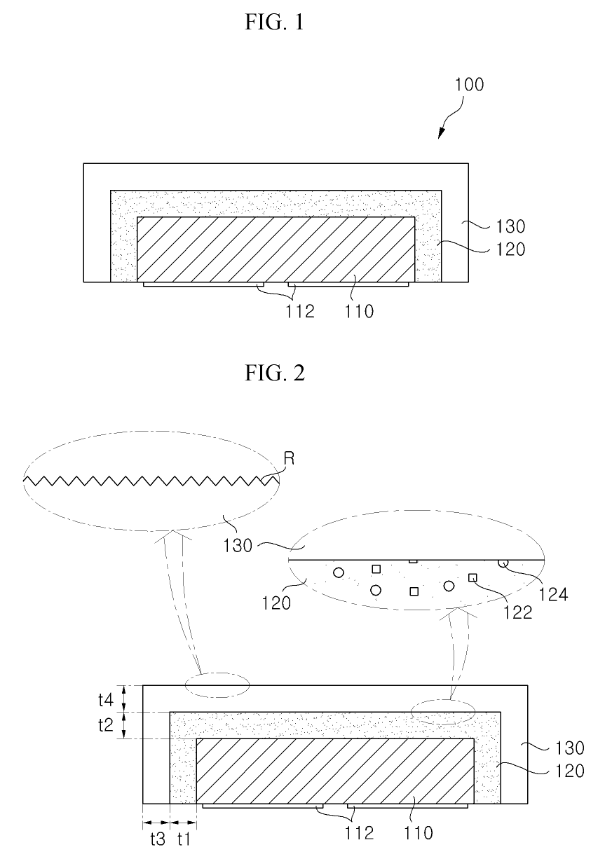

FIG. 1 is a sectional view of a light emitting diode according to one exemplary embodiment of the present disclosure and FIG. 2 is a view illustrating the light emitting diode according to the exemplary embodiment of the present disclosure.

Referring to FIG. 1 and FIG. 2, the light emitting diode according to one exemplary embodiment includes a light emitting diode chip 110, a first molding portion 120, and a second molding portion 130.

The light emitting diode chip 110 may be mounted on a substrate (not shown) and may be configured to emit blue light or UV light. The light emitting diode may include a plurality of light emitting diode chips 110, as needed. In one exemplary embodiment, the light emitting diode chip 110 includes an n-type semiconductor layer and a p-type semiconductor layer and emits light through recombination of holes and electrons. To this end, an active layer may be interposed between the n-type semiconductor layer and the p-type semiconductor layer. The light emitting diode chip 110 may have a lateral type, vertical type or flip-chip type structure.

In the structure wherein the light emitting diode chip 110 is mounted on the substrate, the light emitting diode chip 110 may be electrically connected to a plurality of conductive patterns formed on an upper surface of the substrate.

A pair of electrode pads 112 may be formed on a lower surface of the light emitting diode chip 110 to be electrically connected to the conductive patterns on the substrate. In various exemplary embodiments, the electrode pads 112 may be generally coplanar with the lower surface of the light emitting diode chip 110 and may extend in a downward direction of the light emitting diode chip 110, as shown in FIG. 1 and FIG. 2. In some exemplary embodiments, the electrode pads 112 may be placed higher than the lower surface of the light emitting diode chip 110.

The pair of electrode pads 112 may be electrically connected to the conductive patterns of the substrate such that external power can be supplied to the light emitting diode chip 110 through the electrode pads 112.

The substrate provides a mounting seat for the light emitting diode chip 110, and may be an insulation substrate or a conductive substrate. Alternatively, the substrate may be a printed circuit board having conductive patterns formed on an upper surface thereof. If the substrate is the insulation substrate, the substrate may include a polymer material or a ceramic material, for example, a ceramic material having high thermal conductivity, such as AlN. If the substrate is the PCB having conductive patterns thereon, the substrate may include a base and conductive patterns including at least two electrodes.

The first molding portion 120 is formed to cover the light emitting diode chip 110 and may include a polymer resin such as silicone or a ceramic material such as glass or alumina. In the exemplary embodiment, the first molding portion 120 is formed to cover the entirety of the light emitting diode chip 110 including a side surface thereof. That is, the first molding portion 120 may be formed to enclose the light emitting diode chip 110 through conformal coating. As a result, light emitted from the light emitting diode chip 110 can be discharged through the first molding portion 120.

As described above, the first molding portion 120 may include a transparent silicone resin or glass. In this exemplary embodiment, the first molding portion 120 is formed of a silicone resin having an index of refraction of about 1.53.

The first molding portion 120 may include one or more kinds of phosphors 122, 124. The first phosphors 122 may include at least one selected from among one or more kinds of green phosphors, one or more kinds of cyan phosphors, one or more kinds of yellow phosphors and one or more kinds of red phosphors. By way of example, the first phosphors 122 may include garnet phosphors, aluminate phosphors, sulfide phosphors, oxynitride phosphors, nitride phosphors, fluoride phosphors, and silicate phosphors. With this structure, the light emitting diode can emit various colors through wavelength conversion of light emitted from the light emitting diode chip 110.

The above-mentioned garnet phosphor may be selected from either a YAG (Yttrium Aluminum Garnet) phosphor or a LuAG (Lutetium Aluminum Garnet) phosphor. The yttrium of the YAG phosphor could be substituted with Gadolinium (Gd), and the aluminum of the YAG phosphor could be substituted with Galium (Ga). The YAG phosphor has a composition of (Y₁₋ₐGdₐ)₃(Al_{1-b}Ga_{b})₅O₁₂:Ce, 0≦a≦1, 0≦b≦1, and this composition normally is used in Y₃(Al₁₋ₓGaₓ)₅O₁₂:Ce, or (Y₁₋ₐG_{da})₃ Al₅O₁₂:Ce and emits green to yellow or yellowish orange light, depending on adjusting element ratio. If the amount of Ga is increased, the wavelength of the phosphor is shifted to a shorter wavelength closer to green light. If the amount of Gd is increased, the wavelength of the phosphor is shifted to a longer wavelength closer to yellow or yellowish orange light. Y may be substituted with Lu in an LuAG phosphor in the composition of the YAG phosphor as (Lu₁₋ₐGdₐ)₃(Al_{1-b}Ga_{b})₅O₁₂:Ce, 0≦a≦1, 0≦b≦1. The LuAg phosphor has shorter wavelength than the YAG phosphor. In addition, the Al of the LuAG phosphor may be substituted with Ga, which is then referred to as Ga-doped LuAG or Ga-LuAG. Ga-LuAG has a shorter wavelength than LuAG. Lutetium is normally more expensive than Yttrium, and the user may select the phosphor depending on cost, property, and situation of the application.

The Oxynitride phosphor is a territory of a SiAlON (Silicon Aluminum Oxide Nitride) phosphor. The Ca-α-SiAlON phosphor emits amber light and the β-SiAlON:Eu emits green light. β-SiAlON:Eu²⁺ has a narrower emission peak wavelength than the YAG or LuAG phosphor. Thus, if β-SiAlON:Eu²⁺ is used in an LCD display, the LCD display can show a high color gamut property as compared with the YAG phosphor.

A nitride phosphor is a territory of a CASN (Calcium Aluminum Silicon Nitride) phosphor or Sr-CASN, which provides red light, and its composition is expressed as (Sr, Ca) AlSi N3:Eu. Ca can be substituted for Sr and the wavelength is shorter when the amount of Sr increases. The other phosphors are (Sr Ba Ca)₂ Si₅ N₈:Eu emitting red light and La₃ Si₆ N₁₁: Ce emitting yellow light.

A fluoride phosphor can have a composition of A₂MF6: Mn⁴⁺, where A can be selected from K, Na and Rb, and M can be selected from Si, Ge, Sn, Pb, Al, Ga, In and Ti. An A₂MF₆: Mn⁴⁺ phosphor emits a red wavelength of light and shows a narrow emission peak wavelength less than 10 μm because Mn⁴⁺ is used as an activator. Since the output color of the A₂MF₆: Mn⁴⁺ phosphor provides high color purity due to the narrow emission peak wavelength, if the A₂MF₆: Mn⁴⁺ phosphor is used in a display, the display may easily realize a wide color range over NTSC (National Television System Committee) 85%, or instead over NTSC 90%, since the output color of the A₂MF₆: Mn⁴⁺ phosphor provide high color purity due to the narrow emission peak wavelength. However, the A₂MF₆: Mn⁴⁺ phosphor typically has low reliability. One of the reasons why the A₂MF₆: Mn⁴⁺ phosphor has low reliability is that Mn is sensitive to H₂O. If it is necessary to use the A₂MF₆: Mn⁴⁺ phosphor, it may be desirable to take a step to increase the reliability of the A₂MF₆: Mn⁴⁺ phosphor. A first way to increase the reliability of the A₂MF₆: Mn⁴⁺ phosphor is to control the molar amount of the Mn. For example, Mn has a molar range about 0.02 to about 0.1 times that of M in the A₂MF₆: Mn⁴⁺ phosphor. If the Mn to M molar ratio is less than 0.02, the light output of the A₂MF₆: Mn⁴⁺ phosphor is rapidly decreased. If the Mn to M molar ratio is greater than 0.1, the reliability of A₂MF₆: Mn⁴⁺ phosphor decreases critically. A second way to increase the reliability of the A₂MF₆: Mn⁴⁺ phosphor is to cover the surface of the A₂MF₆: Mn⁴⁺ phosphor using the material A₂MF₆ or fluoride without Mn. The covered material could be fixed to partially cover the A₂MF₆: Mn⁴⁺ phosphor or cover the entire surface of the A₂MF₆: Mn⁴⁺ phosphor. A third way to increase the reliability of the A₂MF₆: Mn⁴⁺ phosphor is to cover the mold resin, which contains the A₂MF₆: Mn⁴⁺ phosphor of the LED, using additional resin material. The user can select one of these ways or mix them to increase reliability.

If the light emitting diode chip 110 is configured to emit light having a peak wavelength in a blue wavelength band, the first phosphors 122 contained in the first molding portion 120 may be selected from any kinds of phosphors capable of emitting light having a longer peak wavelength than blue light (for example, green light, red light or yellow light). Alternatively, if the light emitting diode chip 110 is configured to emit UV light, the first phosphors 122 contained in the first molding portion 120 may be selected from any kinds of phosphors capable of emitting light having a longer peak wavelength than UV light (for example, blue light, green light, red light or yellow light).

With this structure, the light emitting diode can emit white light. However, it should be understood that this structure is illustrated by way of example and other implementations are also possible. In the exemplary embodiment, the first molding portion 120 may include one or more kinds of phosphors.

As described above, the first molding portion 120 includes one or more kinds of first phosphors 122, whereby an overall index of refraction of the first molding portion 120 is increased to about 1.9 to 2.0. This is because the index of refraction of the first phosphors 122 contained in the first molding portion 120 is higher than the index of refraction of the silicon resin.

Further, in order to form the first molding portion 120 so as to cover the light emitting diode chip 110, the first molding portion 120 including one or more kinds of first phosphors 122 is deposited in a liquid phase on the light emitting diode chip 110 to cover the light emitting diode chip 110, followed by curing, grinding, and cutting. In this process, as shown in FIG. 2, the first phosphors 122 contained in the first molding portion 120 can be partially cut. As a result, when light emitted from the light emitting diode chip 110 is discharged through the partially cut first phosphors 122 while passing through the first molding portion 120, the index of refraction can be further increased.

As such, since there is a great difference in index of refraction between the first molding portion 120 including one or more kinds of first phosphors 122 and external air, the quantity of light emitted from the light emitting diode chip 110 can be reduced. Accordingly, in the exemplary embodiment, the second molding portion 130 may be formed to cover the first molding portion 120.

The second molding portion 130 may be formed of the same kind of material as the material of the first molding portion 120, and does not include the first phosphors 122 unlike the first molding portion 120. That is, the second molding portion 130 may include a polymer resin such as a transparent silicone resin, or a ceramic material such as glass or alumina. The second molding portion 130 is formed to cover the entirety of the first molding portion 120 including a side surface thereof. That is, the second molding portion 130 may be formed to enclose the first molding portion 120 through conformal coating. Accordingly, light emitted from the light emitting diode chip 110 is discharged through the second molding portion 130 via the first molding portion 120.

The second molding portion 130 is formed of a transparent silicone resin or glass and thus may have an index of refraction of about 1.53, as described above. Accordingly, light emitted from the light emitting diode chip 110 is discharged through the first molding portion 120 having an index of refraction of about 1.9 to 2.0 and the second molding portion 130 having an index of refraction of about 1.53.

In this way, since light emitted from the light emitting diode chip 110 is discharged through two molding portions having different indices of refraction, the difference in index of refraction between the molding portions and external air can be reduced, thereby further improving the quantity of light emitted through the two molding portions.

Furthermore, a roughness R may be formed on an upper surface of the second molding portion 130. The roughness R may be formed thereon by grinding the upper surface of the second molding portion 130 and serves to reduce reflection of light at an interface between the second molding portion 130 and external air due to a difference in index of refraction therebetween. Accordingly, while light emitted from the light emitting diode chip 110 is discharged through the second molding portion 130 via the first molding portion 120, the light emitting diode according to this exemplary embodiment can reduce reflection of light at the interface, thereby further improving the quantity of light emitted from the light emitting diode. In addition, the roughness R may also be formed on a side surface of the second molding portion 130 and on the first molding portion 120.

In this exemplary embodiment, a thickness t1 of a lateral side of the first molding portion 120 covering the side surface of the light emitting diode chip 110 is the same as a thickness t2 of an upper side of the first molding portion 120 covering the upper surface of the light emitting diode chip 110. In addition, a thickness t3 of a lateral side of the second molding portion 130 covering the side surface of the first molding portion 120 is the same as a thickness t4 of an upper side of the second molding portion 130 covering the upper surface of the first molding portion 120. In addition, the thickness t1 of the first molding portion 120 is the same as the thickness t3 of the second molding portion 130. By way of example, the first molding portion 120 may cover the side surface and the upper surface of the light emitting diode chip 110 in a thickness of about 100 μm, and the second molding portion 130 may cover the side surface and the upper surface of the first molding portion 120 in a thickness of about 100 μm.

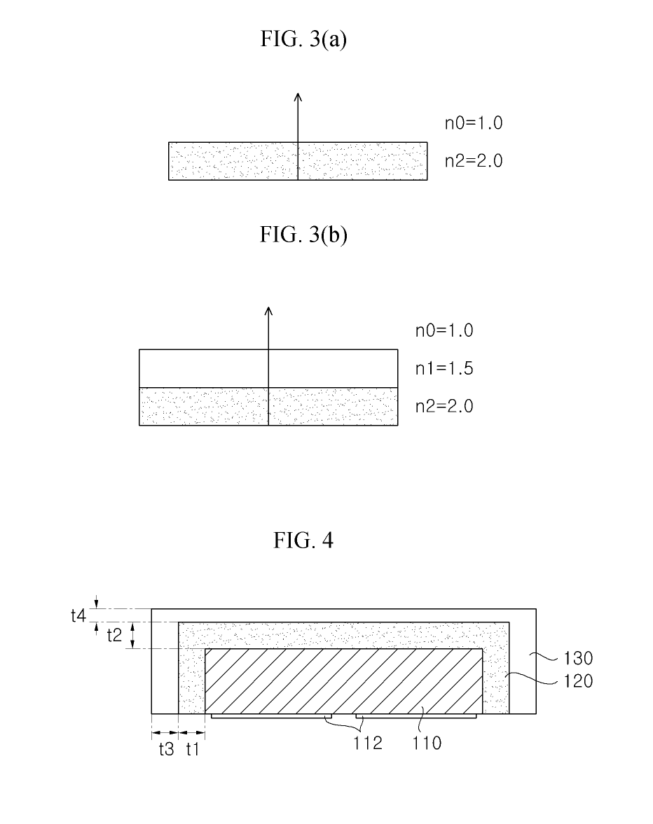

FIG. 3(a) is a view illustrating light transmittance at an interface between a medium having an index of refraction of 2.0 and air having an index of refraction of 1.0, and FIG. 3(b) is a view illustrating light transmittance at interfaces between a medium having an index of refraction of 2.0, a medium having an index of refraction of 1.5 and air having an index of refraction of 1.0.

When light travels from a medium having an index of refraction of 2.0 to air as shown in FIG. 3(a), light transmittance can be calculated based on reflectivity at an interface between the media. Reflectivity at an interface between media having different indices of refraction can be calculated by Equation 1:

$$R ( \% ) = {( \frac{{n}_{2} - {n}_{1}}{{n}_{2} + {n}_{1}} )}^{2} \times 100.$$

In FIG. 3(a), reflectivity at an interface between a medium (n2) and air (n0) is about 11.1% according to this equation, and thus it can be confirmed that transmittance of light discharged from the medium (n2) is about 88.9%.

When light is discharged to air from a medium having an index of refraction of 2.0 through a medium having an index of refraction of 1.5, reflectivity at each of interfaces between the media can be calculated using the above equation as follows.

Reflectivity at an interface between a medium (n2) and a medium (n1) is about 2% and reflectivity at an interface between the medium (n1) and air (n0) is about 4%. Thus, it can be confirmed that transmittance of light discharged from the medium (n2) to air is about 94%. In this way, the light emitting diode can increase transmittance of light by decreasing the difference in index of refraction between media.

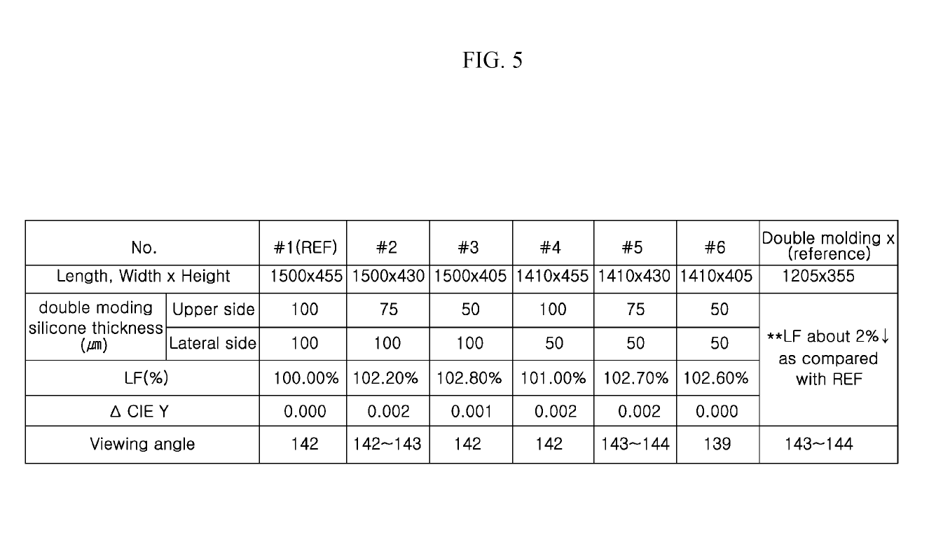

FIG. 4 is a sectional view of a light emitting diode according to another exemplary embodiment of the present disclosure, and FIG. 5 shows a table of test results as to quantity of light depending upon thickness of a second molding portion.

Referring to FIG. 4, the light emitting diode according to this exemplary embodiment includes a light emitting diode chip 110, a first molding portion 120, and a second molding portion 130. A repeated description of the same components as those of the above exemplary embodiment will be omitted.

As shown in FIG. 4, the first molding portion 120 is formed to cover the light emitting diode chip 110 and the second molding portion 130 is formed to cover the first molding portion 120, as in the above exemplary embodiment. In this exemplary embodiment, a thickness t4 of an upper side of the second molding portion 130 covering an upper surface of the first molding portion 120 may be smaller than a thickness t3 of a lateral side of the second molding portion 130 covering a side surface of the first molding portion 120.

In FIG. 5, it can be seen that the quantity of light emitted from the light emitting diode increases with decreasing thickness t4 of the upper side of the second molding portion 130. In addition, a beam angle of light emitted from the light emitting diode varies depending upon the thickness t4 of the upper side of the second molding portion 130 such that the beam angle increases with increasing thickness thereof.

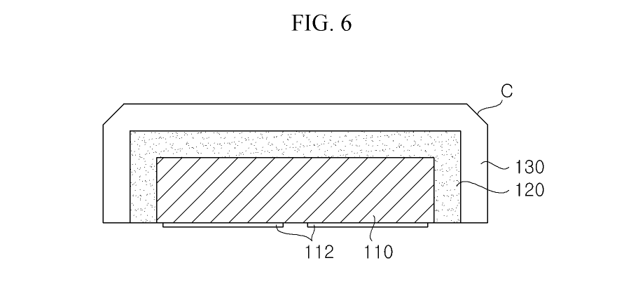

FIG. 6 is a sectional view of a light emitting diode according to a further exemplary embodiment of the present disclosure.

Referring to FIG. 6, the light emitting diode according to this exemplary embodiment includes a light emitting diode chip 110, a first molding portion 120, and a second molding portion 130. A repeated description of the same components as those of the above exemplary embodiment will be omitted.

The second molding portion 130 is formed to cover the first molding portion 120 and may have an inclined surface C formed by chamfering a portion or the entirety of a corner thereof. With this structure, the light emitting diode can minimize distortion of light emitted from the light emitting diode chip 110 at the corner of the second molding portion 130 while light is discharged through the second molding portion 130. That is, an upper surface of the second molding portion 130 may include a flat surface and the inclined surface C such that light traveling towards the corner of the second molding portion 130 can be discharged to the outside through the inclined surface (C). The inclined surface (C) may include a curved surface.

As such, with the structure wherein the second molding portion 130 has an inclined surface at the corner thereof, the light emitting diode can prevent reduction in quantity of light emitted through an upper corner of the second molding portion 130 and enlargement of an internal passage of light passing through the interior of the second molding portion 130. As a result, the light emitting diode can achieve uniform discharge of light through the second molding portion 130.

Since the light emitting diode of the present invention is manufactured without a substrate which supports the light emitting diode chip, the light emitting diode may have small size and can reduce the cost including material cost and manufacturing cost. This because normally the light emitting diode has the substrate and at least a pair of electrodes disposed on the substrate. A small size provides several advantages in many applications. For example, a user can add more of the light emitting diodes while maintaining the same size of the apparatus used in a given application, or insert other components, such as a lens, into the apparatus, which may have a space restriction. The apparatus includes the substrate and the light emitting diode mounted on the substrate. A lens may cover the light emitting diode depending on the application. The material of the lens may include PC, PMMA, and silicone. Silicone is a more durable material but it is more expensive than PC and PMMA. The lens may be attached to the substrate with an adhesive member or a fastener, such as, for example, a clip or hinge. The adhesive member may include an adhesive resin such as epoxy, silicone, etc., which adheres the lens to the substrate with specific pressure. The adhesive material may be selected according to the material of the lens. If the user selects silicone for the material of the lens, the user may prefer to select silicone for the lens adhesive since the silicone has a higher cure temperature and operating temperature than epoxy resin. The silicone lens can withstand relatively high temperatures. Silicone adhesive normally has higher viscosity and hardness comparing to epoxy and these characteristics make it difficult to control the lens. Therefore, if the user selects PC or PMMA, the user may instead select an epoxy adhesive. The user may need to control the temperature for curing the epoxy adhesive between 70˜90° C. Curing temperature of the epoxy adhesive for this invention is 70˜90° C. If the temperature is less than 70° C., it is difficult to attach the lens to the substrate since the temperature for curing the adhesive is greater than 70° C. If the temperature is greater than 90° C., it is easy to make a deflection in the lens when the lens is made by PMMA. PMMA makes the heat deflection starting from 85˜90° C. and PC makes the heat deflection starting from 110˜120° C. If the application is used in an environment between 90° C. and 120° C. after the lens attachment process with the epoxy adhesive, the user may choose to select PC rather than PMMA as a lens material. If the user wishes to apply a reflow process or a high temperature process after lens attachment, the user may choose to select a silicone lens and a silicone adhesive, since the heat deflection temperature of the silicone lens is higher than the reflow temperature.

| Category | Property | PC | PMMA | Glass |
|---|---|---|---|---|
| Properties of | Transmission [%] | 86~89 | 89~92 | 92 |
| Optical | Index of Refraction (RI) | 1.59 | 1.49 | 1.5~1.6 |
| Clarity, | Haze % | 1~3 | 2~4 | — |
| 2 mm | Abbe number | 34 | 57 | 39~59 |

| Category | Property | PC | PMMA | Glass |
|---|---|---|---|---|
| Properties of | Transmission [%] | 86~89 | 89~92 | 92 |
| Optical Clarity, | Index of Refraction (RI) | 1.59 | 1.49 | 1.5~1.6 |
| 2 mm | Abbe number | 34 | 57 | 39~59 |

A “transmission property” refers to the degree that light can pass through a medium. The higher the transmission rate the greater the amount of light passing through. This property may significantly influence the efficiency of the optical system.

The “Index of Refraction” is related to how much light changes direction in the medium. The higher the Index of Refraction the greater the degree of change in the direction. If the lens is needed to spread more, the user selects the material which has a higher Index of Refraction value.

“Abbe number” is related to color aberration, which is the extent to which the lens blurs or “rainbows” colors, especially in the periphery. The higher the Abbe number, the lower the color aberration.

The user may select the lens and adhesive material considering the above mentioned property. The user needs to consider the application and the situation in which the apparatus is used.

If the application has a process including high temperature over 120° C. after lens attachment or is operated in high temperature over 120° C., the user may have to select a silicone lens and a silicone adhesive.

If the application has a process including high temperature over 90° C. but under 120° C., and the user wishes to design the lens which has a high degree of light direction change, the user may select a PC lens.

If the application has a process including a high temperature under 85˜90° C. and the light direction change is not a significant issue, the use of PMMA may be best option in certain application.

The lens may focus or disperse the lights from the light emitting diode chip depending on the application. Focusing the light is useful in flood light spotlight and so on, and dispersing the light is useful in backlight for LCD display, flat panel light for lighting, channel letter etc. The user can make lighting module using the lens and a printed circuit board with the light emitting diode. The light emitting diode could be mounted on the printed circuit board, which connects the light emitting diode with an electrical source and then the lens cover the light emitting diode.

When the light emitting diode is applied to a backlight, an important goal is to spread the light from the light emitting diode chip to obtain uniform light distribution. If the application is for a thinner display, the user has to consider the method of removing a “hot spot”. Spreading the light from the light emitting diode chip is effectively accomplished by a lens. However, the thickness of the backlight could be greater than before using the lens. At this time, the light emitting diode of the present invention will be an effective way to reduce the thickness of the backlight.

Although certain exemplary embodiments have been described herein, it should be understood by those skilled in the art that these embodiments are given by way of illustration only, and that various modifications, variations, and alterations can be made without departing from the spirit and scope of the invention. Therefore, the scope of the invention should be limited only by the accompanying claims and equivalents thereof.

What is claimed is:

1. A light emitting apparatus, comprising:
a substrate;
a light emitting diode disposed on the substrate; and
a lens covering the light emitting diode,
wherein:
the light emitting diode comprises:
a light emitting diode chip;
a first molding portion covering the light emitting diode chip;
a second molding portion covering the first molding portion; and
the first molding portion comprises at least one or more kinds of phosphors and the second molding portion contains no phosphors.

2. The light emitting apparatus of claim 1, wherein the phosphors comprise at least one selected from a green phosphor, a cyan phosphor, a yellow phosphor, and a red phosphor.

3. The light emitting apparatus of claim 1, wherein the phosphors comprise at least one selected from a garnet phosphor, an aluminate phosphor, a sulfide phosphor, an oxynitride phosphor, a nitride phosphor, a fluoride phosphor, and a silicate phosphor.

4. The light emitting apparatus of claim 3, wherein the fluoride phosphor have a composition of A₂MF₆: Mn⁴⁺, where A is selected from K, Na, and Rb, and M is selected from Si, Ge, Sn, Pb, Al, Ga, In, and Ti.

5. The light emitting apparatus of claim 4, wherein the A₂MF₆: Mn⁴⁺ phosphor is configured to emit light having a red wavelength and a narrow emission peak wavelength less than 10 μm.

6. The light emitting apparatus of claim 4, wherein a surface of the A₂MF₆: Mn⁴⁺ phosphor is covered by the material A₂MF₆ without Mn or fluoride.

7. The light emitting apparatus of claim 3, wherein the oxynitride phosphor comprises β-SiAlON:Eu²⁺.

8. A light emitting diode, comprising:
a light emitting diode chip;
a first molding portion covering the light emitting diode chip;
a second molding portion covering the first molding portion,
wherein:
the first molding portion comprises one or more kinds of phosphors and the second molding portion contains no phosphors
the first molding portion has a rectangular shape and the second molding portion has a rectangular shape.

9. The light emitting diode of claim 8, a total thickness of the first molding portion and second molding portion is less than the half of the chip width in a horizontal direction.

10. The light emitting diode of claim 8, the second molding portion has a thickness less than that of the first molding portion.

11. The light emitting diode of claim 8, wherein the phosphors comprise at least one selected from a green phosphor, a cyan phosphor, a yellow phosphor, and a red phosphor.

12. The light emitting diode of claim 8, wherein the phosphors comprise at least one selected from a garnet phosphor, an aluminate phosphor, a sulfide phosphor, an oxynitride phosphor, a nitride phosphor, a fluoride phosphor, and a silicate phosphor.

13. The light emitting diode of claim 12, wherein the fluoride phosphor has a composition of A₂MF₆: Mn⁴⁺, where A is selected from K, Na and Rb, and M is selected from Si, Ge, Sn, Pb, Al, Ga, In and Ti.

14. The light emitting diode of claim 13, wherein the A₂MF₆: Mn⁴⁺ phosphor is configured to emit light having a red wavelength and a narrow emission peak wavelength less 10 μM.

15. The light emitting diode of claim 13, wherein a surface of the A₂MF₆: Mn⁴⁺ phosphor is covered by the material A₂MF₆ without Mn or fluoride.

16. The light emitting diode of claim 12, wherein the oxynitride phosphor comprises β-SiAlON:Eu²⁺.
